(19) United States
(12) Patent Application Publication
(10) Pub. No.: US 2024/0412957 A1
(43) Pub. Date: Dec. 12, 2024

(54) HIGH TEMPERATURE BIASABLE HEATER WITH ADVANCED FAR EDGE ELECTRODE, ELECTROSTATIC CHUCK, AND EMBEDDED GROUND ELECTRODE

(71) Applicant: Applied Materials, Inc., Santa Clara, CA (US)

(72) Inventors: Gautam PISHARODY, Newark, CA (US); Onkara Swamy KORA SIDDARAMAIAH, Santa Clara, CA (US); Vijay D. PARKHE, San Jose, CA (US); Douglas A. BUCHBERGER, Jr., Livermore, CA (US); Qiwei LIANG, Fremont, CA (US); Dmitry LUBOMIRSKY, Cupertino, CA (US)

(73) Assignee: Applied Materials, Inc., Santa Clara, CA (US)

(21) Appl. No.: 18/207,042

(22) Filed: Jun. 7, 2023

(51) Int. Cl. H01J 37/32; H01L 21/683

(52) U.S. Cl. CPC H01J 37/32724; H01J 37/32568; H01L 21/6833; H01J 2237/2007; H01J 2237/332

(57) ABSTRACT

Examples of a substrate support are provided herein. In some examples, the substrate support has a ceramic electrostatic chuck having a body. The body has a first side configured to support a substrate and a second side opposite the first side. The body has a chucking electrode, an active edge electrode disposed adjacent the chucking electrode, a floating mesh disposed below the chucking electrode, a heater disposed below the floating mesh, and a ground mesh disposed below the heater, wherein the ground mesh is adjacent the second side.

### BACKGROUND

### Field

Examples of the present disclosure generally relate to apparatus and methods for fabricating semiconductor devices. More specifically, apparatus disclosed herein relate to an electrostatic chuck assembly for use in a plasma processing chamber.

### Background of the Related Art

The fabrication of microelectronic devices typically involves a complicated process sequence requiring hundreds of individual processes performed on semi-conductive, dielectric, and conductive substrates. Examples of these processes include oxidation, diffusion, ion implantation, thin film deposition, cleaning, etching, and lithography, among other operations. Each operation is time consuming and expensive.

With ever-decreasing critical dimensions for microelectronic devices, the design and fabrication for these devices on substrates is becoming or has become increasingly complex. Control of the critical dimensions and process uniformity becomes increasingly more significant. Complex multilayer stacks used to make microelectronic devices involve precise process monitoring of the critical dimensions for the thickness, roughness, stress, density, and potential defects. Process recipes for forming the devices have multiple incremental processes to ensure critical dimensions are maintained. Typically, each incremental process may utilize one or more processing chambers that adds additional time for forming the devices and also increases opportunities for forming defects.

As critical dimensions on these devices shrink, past fabrication techniques encounter new hurdles. For example, one operation used in the fabrication is a metal bottom up trench fill in the formation of these devices. As the smaller critical dimensions for these devices shrink, the fill material tends to close off the top of the trench prior to completely filling at the bottom. Additionally, process skew may occur due to the plasma coupling to an electrostatic chuck, supporting a substrate during device formation, and/or non-uniformity of the temperature across the electrostatic chuck, negatively impacting process performance. To achieve good bottom up fill and prevent process skew, conventional solutions require the utilization of a variety of specialized chambers. However, multiple operations over multiple processing chambers add to production costs and complexity.

Therefore, there is a need for an improved processing system.

### SUMMARY

Examples of a substrate support are provided herein. In some examples, the substrate support has a ceramic electrostatic chuck having a body. The body has a first side configured to support a substrate and a second side opposite the first side. The body has a chucking electrode, an active edge electrode disposed adjacent the chucking electrode, a floating mesh disposed below the chucking electrode, a heater disposed below the floating mesh, and a ground mesh disposed below the heater, wherein the ground mesh is adjacent the second side.

In another example, a processing chamber is provided. The processing chamber has a chamber body and a substrate support disposed within an inner volume of the chamber body. The substrate support has a ceramic electrostatic chuck having a body. The body has a first side configured to support a substrate and a second side opposite the first side. The body has a chucking electrode, an active edge electrode disposed adjacent the chucking electrode, a floating mesh disposed below the chucking electrode, a heater disposed below the floating mesh, and a ground mesh disposed below the heater, wherein the ground mesh is adjacent the second side.

### BRIEF DESCRIPTION OF THE DRAWINGS

So that the manner in which the above recited features of the present invention can be understood in detail, a more particular description of the invention, briefly summarized above, may be had by reference to implementations, some of which are illustrated in the appended drawings. It is to be noted, however, that the appended drawings illustrate only typical implementations of this invention and are therefore not to be considered limiting of its scope, for the invention may admit to other equally effective implementations.

FIG. 1 depicts a schematic side view of a process chamber having a substrate support in accordance with at least some examples of the present disclosure.

FIG. 2A depicts a schematic partial side view of the substrate support in accordance with one example of the present disclosure.

FIG. 2B depicts a blow up of a portion of the substrate support shown in FIG. 2A.

FIG. 3 depicts a schematic partial side view of the substrate support in accordance with another example of the present disclosure.

To facilitate understanding, identical reference numerals have been used, where possible, to designate identical elements that are common to the figures. It is contemplated that elements disclosed in one implementation may be beneficially used in other implementations without specific recitation.

### DETAILED DESCRIPTION

In the present disclosure, an electrostatic chuck assembly is provided which has an edge ring resting on a ceramic plate. The ceramic plate supports a substrate during plasma processing. The ceramic plate has heaters that can heat the substrate up to 700 degrees C. The ceramic plate has separate chucking electrodes for chucking the substrate and the edge ring. A radio frequency (RF) electrode (edge electrode) is extended to the very edge of the ceramic plate for a denser plasma at the substrate edges hence reducing the edge exclusion region on the substrate to increase throughput. A control of the film profile on the substrate can be maintained while operating at frequencies from 350 kHz to 60 MHz. The ceramic plate enables RF pulsing at very low duty cycles with a pulsing frequency between 0.2 Hz to 20 Hz to prevent film damage by enabling bottom-up trench fill. The low duty cycle RF pulsing at the 0.2 Hz to 20 Hz level, can be utilized for plasma enhanced chemical vapor deposition (PECVD) and plasma enhanced atomic layer deposition (PEALD) processes which enable bottom-up filling of trenches by preventing the sidewalls of the trenches from closing in during the fill, which deters porous film formation in the trenches.

An embedded ground RF electrode helps to prevent RF coupling to the chamber bottom, thereby reducing required chamber depth, and thus, the chamber volume. The reduced chamber volume beneficially reduces the purge time required during a PEALD process.

Advantageously, the high temperature electrostatic chuck assembly can perform both PECVD/PEALD deposition as well as in-situ etch/treatment processes all while using the same ceramic plate. The electrostatic chuck assembly enables improved film edge coverage using the edge electrode. The electrostatic chuck assembly additionally has a reduced footprint due to an embedded ground electrode that also makes the electrostatic chuck assembly more reliable by avoiding plasma light up in the gaps as seen in previous approaches to grounding.

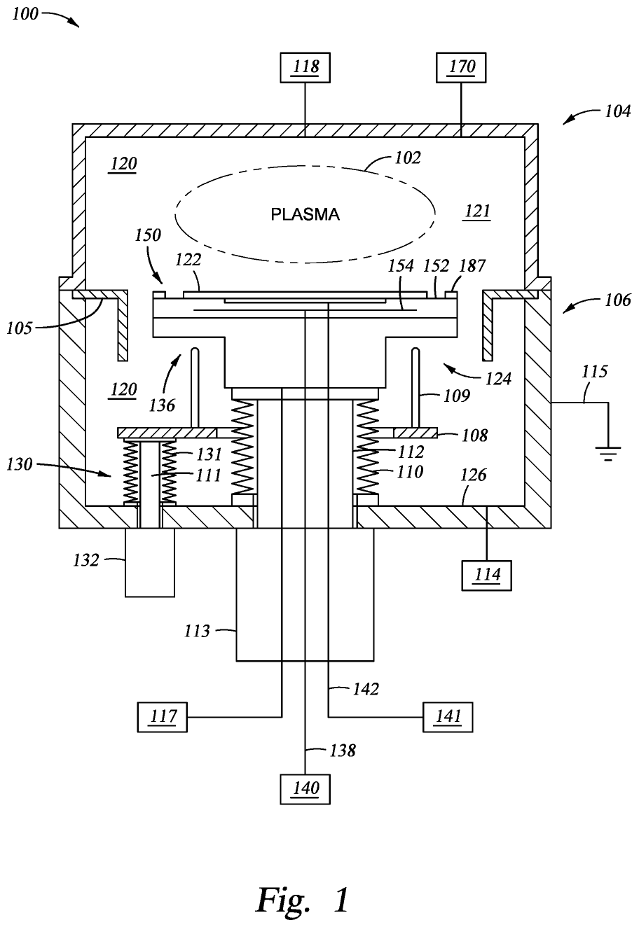

FIG. 1 depicts a schematic side view of a plasma processing chamber 100 having a substrate support 124 in accordance with at least some examples of the present disclosure. In some examples, the plasma processing chamber 100 is an etch processing chamber. However, other types of processing chambers configured for different processes can also use or be modified for use with examples of the substrate support 124 described herein.

The plasma processing chamber 100 is a vacuum chamber that is suitably adapted to maintain sub-atmospheric pressures within a chamber interior volume 120 during substrate processing. The plasma processing chamber 100 includes a chamber body 106 covered by a lid 104 which encloses a processing volume 121 located in the upper portion of the chamber interior volume 120 above the substrate support 124. The plasma processing chamber 100 may also include one or more liners 105 circumscribing various chamber components to prevent unwanted reaction between such components and ionized process material. The chamber body 106 and lid 104 may be made of metal, such as aluminum. The chamber body 106 may be grounded via a coupling to ground 115.

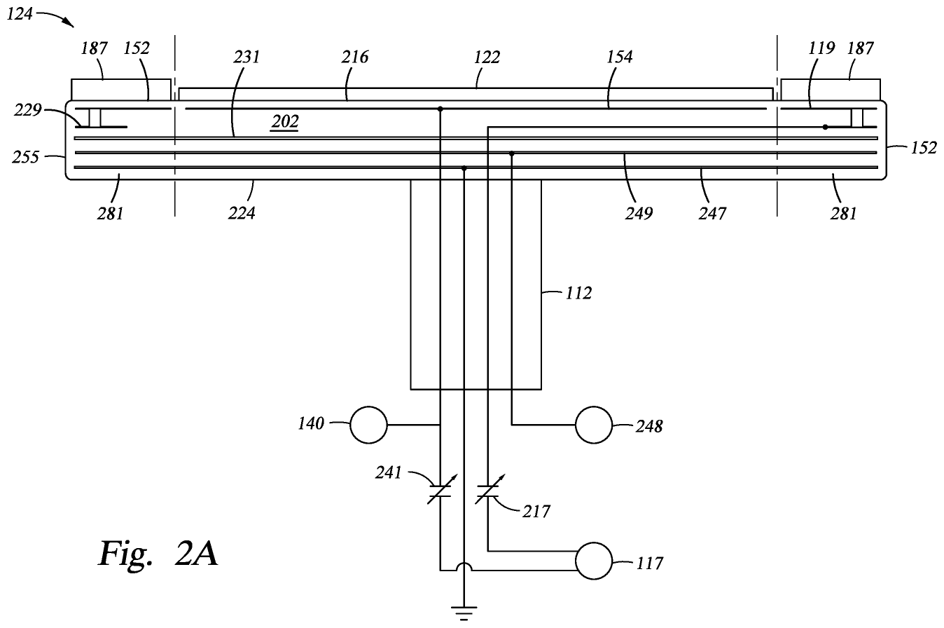

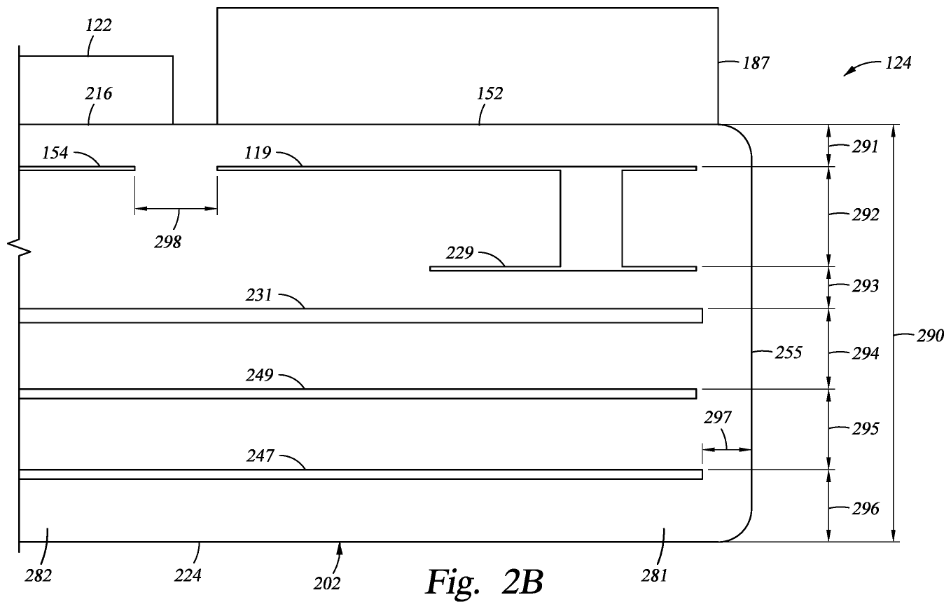

The substrate support 124 is disposed within the chamber interior volume 120 to support and retain a substrate 122 thereon, such as a semiconductor wafer. The substrate support 124 may generally comprise an electrostatic chuck assembly 150 (described in more detail below with respect to FIG. 2B) and a hollow support shaft 112 for supporting the electrostatic chuck assembly 150. The electrostatic chuck assembly 150 comprises an electrostatic chuck 152 having one or more chucking electrodes 154 disposed therein. An edge ring 187 is disposed on the substrate support 124 and circumscribes the substrate 122. The electrostatic chuck 152 electrostatically chucks the substrate 122 to the substrate support 124.

The hollow support shaft 112 provides a conduit to provide, for example, backside gases, process gases, fluids, coolants, power, or the like, to the substrate support 124. In some examples, the hollow support shaft 120 is attached to a bottom surface of the plasma chamber body 106 and the substrate support 124 is fixed in the processing chamber 100. In other examples, the hollow support shaft 112 is coupled to a lift mechanism 113, such as an actuator or motor, which provides vertical movement of the electrostatic chuck assembly 150 between an upper, processing position (as shown in FIG. 1) and a lower, transfer position (not shown). A bellows assembly 110 is disposed about the hollow support shaft 112 and is coupled between the electrostatic chuck assembly 150 and a bottom surface 126 of plasma processing chamber 100 to provide a flexible seal that allows vertical motion of the electrostatic chuck assembly 150 while preventing loss of vacuum from within the plasma processing chamber 100.

The hollow support shaft 112 provides a conduit for coupling a backside gas supply 141, a negative pulsed DC power source 140, and a bias power supply 117 to the electrostatic chuck assembly 150. In some examples, the bias power supply 117 includes one or more RF bias power sources. The backside gas supply 141 is disposed outside of the chamber body 106 and supplies heat transfer gas to the electrostatic chuck assembly 150. In some examples, the substrate support 124 may alternatively include AC, DC, or RF bias power.

The substrate support 124 may, or may not, include a substrate lift assembly 130. The substrate lift assembly 130 may include lift pins 109 mounted on a platform 108 connected to a shaft 111 which is coupled to a second lift mechanism 132 for raising and lowering the platform 108 and pins 109 so that the substrate 122 may be placed on or removed from the electrostatic chuck assembly 150. The electrostatic chuck assembly 150 includes through holes to receive the lift pins 109. A bellows assembly 131 is coupled between the substrate lift assembly 130 and the bottom surface 126 to provide a flexible seal that maintains the chamber vacuum during vertical motion of the substrate lift 130. Alternately, the substrate lift assembly 130 may be included entirely inside the processing chamber 100, for example within the substrate support assembly 124.

In some examples, the electrostatic chuck assembly 150 includes gas distribution channels 142 extending from a lower surface of the electrostatic chuck assembly 150 to various openings in an upper surface of the electrostatic chuck assembly 150. The gas distribution channels 142 are configured to provide backside gas, such as nitrogen (N) or helium (He), to the top surface of the electrostatic chuck assembly 150 to act as a heat transfer medium. The gas distribution channels 142 are in fluid communication with the backside gas supply 141 via a conduit to control the temperature and/or temperature profile of the electrostatic chuck assembly 150 during use.

The plasma processing chamber 100 is coupled to and in fluid communication with a pumping system 114 that includes a throttle valve (not shown) and vacuum pump (not shown) which are used to exhaust the plasma processing chamber 100. The pressure inside the plasma processing chamber 100 may be regulated by adjusting the throttle valve and/or vacuum pump. The plasma processing chamber 100 is also coupled to and in fluid communication with a process gas supply 118 that may supply one or more process gases to the plasma processing chamber 100 for processing the substrate 122 disposed therein.

In operation, a plasma 102 is created in the chamber interior volume 120 to perform one or more processes. The plasma 102 may be created by coupling power from a plasma power source (e.g., RF plasma power supply 170) to a process gas via one or more electrodes near or within the chamber interior volume 120 to ignite the process gas and create the plasma 102. A bias power may also be provided from the bias power supply 117 to the one or more chucking electrodes 154 within the electrostatic chuck assembly 150 to attract ions from the plasma 102 towards the substrate 122. The RF plasma power supply 170 may provide RF energy at a frequency of about 40 MHz or greater to the processing chamber 100 for maintaining the plasma 102 therein.

FIG. 2A depicts a schematic partial side view of the substrate support 124 in accordance with at least one example of the present disclosure. FIG. 2B depicts a blow up of a portion of the substrate support shown in FIG. 2A and will be relied on for providing a detailed view for the discussion of feature locations.

The electrostatic chuck 152 has a body 202. The body 202 may be uniformly formed of a ceramic material. In one example, the body 202 is made of AlN, Al₂O₃, quartz, or other suitable material. The body 202 of the electrostatic chuck 152 is fabricated in the form of a ceramic plate with electrodes embedded therein.

The body 202 includes a first side 216 configured to support the substrate 122 and a second side 224 opposite the first side 216. The electrostatic chuck 152 has an outer diameter 255. The body 202 has an inner portion 282 and an outer portion 281 extending to the outer diameter 255 and surrounding the inner portion 282. The substrate 122 is disposed on the inner portion 282 and the edge ring 187 is disposed on the outer portion 281. The body 202 thickness between the first side 216 and the second side 224 is between about 18 mm and 22 mm, such as about 20 mm.

The body 202 of the electrostatic chuck 152 has one or more chucking electrodes 154, an RF floating mesh 231, optionally a spoke mesh 229, one or more heaters 249, and a ground mesh 247. The one or more chucking electrodes 154, RF floating mesh 231, and the spoke mesh 229 may be all be coupled to one or more RF power sources. The one or more chucking electrodes 154 are coupled to a DC power supply and may additionally be optionally coupled to the RF power source.

The one or more chucking electrodes 154 are embedded in the inner portion 282 of the body 202 immediately adjacent to the first side 216. The chucking electrodes 154, when energized, electrostatically chuck the substrate 122 to the first side 216 of the electrostatic chuck 152. The one or more chucking electrodes 154 may be monopolar or bipolar. In some examples, the electrostatic chuck 152 provides Coulombic chucking. In some examples, the electrostatic chuck 152 provides Johnsen-Rahbek chucking. In some examples, the one or more chucking electrodes 154 comprise an upper electrode, a lower electrode (not shown), and a plurality of posts electrically coupled to the upper and lower electrodes. In one or more examples, the chucking electrode may additionally be a RF bias electrode. For example, RF power may be supplied on top of the DC chucking

Adjacent the chucking electrodes 154 is an active far edge electrode 119 disposed in the outer portion 281 of the body 202. The active far edge electrode 119 may be coupled to the bias power supply 117 for biasing and shaping the plasma sheath. The active far edge electrode 119 is configured to operate independently of the chucking electrodes 154. However, the chucking electrodes 154 may optionally be coupled to the bias power supply 117 for shaping the plasma sheath in addition to the chucking power supply. A variable capacitor 241 may be disposed between the bias power supply 117 and the chucking electrodes 154 for isolating the chucking electrodes 154 from the active far edge electrode 119. In one example, the active far edge electrode 119 may be energized while the chucking electrodes 154 are de-energized. However, it should be appreciated that the chucking electrodes 154 may be energized at the same time the active far edge electrode 119 is energized or alternately while the active far edge electrode 119 is de-energized.

In some examples, RF energy supplied by the bias power supply 117 may have a frequency of between about 350 KHz to about 60 MHz. In one example, the bias power supply 117 is configured to generate the RF signal overlaid on a pulsed voltage signal of the negative pulsed DC power source 140. In one example, the voltage waveform of the negative pulsed DC power source 140 may include a pulsed voltage signal range of about at 0.2 Hz to about 20 Hz with a duty cycle ranging from 10% to 100% overlaid with the RF signal of about 350 KHz to about 60 Mhz. The negative pulsed DC power source 140 is configured to provide a power profile to correct plasma sheath bending and maintain a substantially flat plasma sheath profile across the substrate 122.

The edge ring 187 is horizontally disposed above the active far edge electrode 119 in the outer portion 281 of the electrostatic chuck 152. The active far edge electrode 119 may be additionally coupled to a negative pulsed DC power supply (not shown) to chuck the edge ring 187 to the electrostatic chuck 152. The negative pulsed DC power supply is configured to provide a power profile to correct plasma sheath bending and maintain a substantially flat plasma sheath profile along the edge of the substrate 122.

All dimensions discussed further below are taken along the outer diameter 255. For example, the body 202 has a pocket disposed in the center of the first side 216 of the body 202. The pocket is above and extends beyond the length of the chucking electrodes 154. The pocket may extend into the body between about 0.5 mm to about 1.3 mm such as 1 mm. When describing the distance the chucking electrodes 154 are disposed below the first side 216, the distance includes the material of the body 202 not present in the pocket. Thus, when the chucking electrodes 154 are described as disposed 2 mm below the first side 216, the chucking electrodes 154 may be only 1 mm below the surface of the pocket.

The active far edge electrode 119 may be spaced a distance 297 of about 2 mm to about 3 mm from the outer diameter 255. For example, the distance 297 from the active far edge electrode 119 may be about 2.5 mm from the outer diameter 255. The chucking electrodes 154 may be spaced a distance 298 of about 2 mm to about 6 mm, such as about 4 mm from the active far edge electrode 119 adjacent thereto. The chucking electrodes 154 and the active far edge electrode 119 may be a distance 291 of about 1.5 mm to about 3 mm, such as about 2.3 mm, below the first side 216. The active far edge electrode 119 is extended to the very edge of the body 202 so that a denser plasma is obtained at the edges of the substrate 122 which reduces the edge exclusion region on the substrate 122 and in turn increases throughput.

The spoke mesh 229 is horizontally disposed in the body 202 below the active far edge electrode 119 and electrically coupled to the active far edge electrode 119. One or more vertical jumpers couple the spoke mesh 229 and active far edge electrode 119. The bias power supply 117 provides RF energy through the spoke mesh 229 to the active far edge electrode 119. A variable capacitor 217 may be disposed between the bias power supply and the spoke mesh 229. The spoke mesh 229 may additionally act as the RF electrode in the inner portion 282 of the body 202 instead of the one or more chucking electrodes 154. Thus, while the spoke mesh may be used to tune the profile of the plasma sheath above the substrate 122, the spoke mesh 229 does not operate independently of the active far edge electrode 19 when doing so.

In one example, the spoke mesh 229 is shaped with four or six sections radiating outwards from the center of the body 202. In another example, the spoke mesh has greater that six sections radiating outwards from the center of the body 202. In another example, the spoke mesh 229 is disc shaped.

The spoke mesh 229 is spaced a distance 292 of between about 4 mm to about 6 mm, such as about 5 mm from the active far edge electrode 119. The spoke mesh 229 may be spaced about 2 mm to about 3 mm from the outer diameter 255. For example, the distance 297 of the spoke mesh 229 from the outer diameter 255 may be about 2.5 mm.

The pulsing of the bias power supply 117 at very low duty cycles with a pulsing frequency between 0.2 Hz to 20 Hz prevents film damage by enabling bottom-up trench fill. The 0.2 Hz to 20 Hz level pulsing can be utilized for PECVD and PEALD processes for bottom-up filling of the trenches while preventing the sidewalls of the trenches from closing in and thus minimizing porous films.

The body 202 of the electrostatic chuck 152 additionally has the RF floating mesh 231 embedded horizontally in the body 202 and disposed below the spoke mesh 229. The RF floating mesh 231 is not electrically coupled to the system ground or to any powered sources. In one example, the RF floating mesh 231 is unattached to a ground or other electric circuit. The RF floating mesh 231 helps filters out damaging RF signals from entering a non-RF environment. The RF floating mesh 231 is disposed between the RF hot sources, such as the spoke mesh 229, active far edge electrode 119, and chucking electrodes 154, and the non-RF hot features, such as the one or more heating elements 249 and ground mesh 247. The RF Floating mesh 231 minimizes the RF signal from the RF hot sources from coupling to the one or more heating elements 249 or ground mesh 247.

The RF floating mesh 231 is disposed a distance 293 of between about 0.5 mm and about 2.0 mm below the spoke mesh 229. For example, the distance 293 of the RF floating mesh 231 below the spoke mesh 229 is about 1.0 mm. The RF floating mesh 231 may also be spaced about 2 mm to about 3 mm from the outer diameter 255. For example, the distance 297 of the RF floating mesh 231 from the outer diameter 255 may be about 2.5 mm.

The one or more heating elements 249 are embedded in the body 202 below the spoke mesh 229. The heating elements 249 may be disposed a distance 294 of between about 4 mm and about 6 mm below the RF floating mesh 231, such as about 5 mm below the RF floating mesh 231. The heating elements 249 extend horizontally within the body 202 to between about 1.5 mm to about 3 mm from the outer diameter 255 of the body 202. In one example, the distance 297 the heating elements 249 extend horizontally within the body 202 is about 2.5 mm from the outer diameter 255 of the body 202.

The heating elements 249 may be arranged in one or more zones to control a temperature of the electrostatic chuck 152. For example, the heating elements 249 may be arranged in one, two or four zones for supplying a temperature to the substrate 122. The heating elements 249 are coupled to a power source 248, e.g., an AC power source, to power the heating elements 249. The one or more heating elements 249 are configured to supply a temperature to the substrate of about 200 degrees Celsius to about 700 degrees Celsius. For example, the electrostatic chuck 152 is configured to operate at temperatures exceeding 600 degrees Celsius, such as about 650 degrees Celsius.

The ground mesh 247 is embedded in the body 202 below the heating elements 249. The ground mesh 247 is coupled to the system ground. The ground mesh 247 provides a conductive path for energy in the electrostatic chuck 152, such as that from the plasma, to be directed at the system ground and prevent arcing between the electrostatic chuck 152 and the sidewalls of the processing chamber 100.

The ground mesh 247 may be disposed a distance 295 of between about 3 mm and about 5 mm below the heating elements 249, such as about 4 mm below the heating elements 249. The distance 297 the ground mesh 247 extends horizontally within the body 202 is between about 1.5 mm to about 3 mm from the outer diameter 255 of the body 202. In one example, the ground mesh 247 extends horizontally within the body 202 to about 2.5 mm from the outer diameter 255 of the body 202. Additionally, the ground mesh 247 may be disposed a distance 296 of between about 1.5 mm and about 3.5 mm above the second side 224, such as about 2.5 mm above the second side 224. This arrangement places the ground mesh 247 as the closest feature in the body 202 to the second side 224, i.e., bottom surface of the ESC 152.

The embedded ground mesh 247 prevents RF coupling to the chamber bottom as well as plasma light-up in any gaps between the ESC and a ground shield found on conventional electrostatic chucks. The plasma light-up leads to undesired chemical deposition around the heater. The ground mesh 247 additionally helps reduce the depth and hence the internal volume of the processing chamber 100. This reduced volume helps to reduce the purge time required during a PEALD process.

In one example, the substrate 122 is electrostatically chucked onto the electrostatic chuck 152 using HV DC power supply, the temperature of the electrostatic chuck 152 is maintained at desired process temperatures using heater controllers while a thermocouple (also going through the shaft) provides feedback loop control, while RF biasing can be provided using bias power supply 117 as and when required for PEALD and etch/treatment steps.

Advantageously, the electrostatic chuck 152 as arranged can operate at temperatures up to 700 degrees C. along with the RF biasing capability to produce a denser plasma at the edges of the wafer. Additionally, the ground mesh 247 is embedded within the body 202 of the electrostatic chuck 152 to prevent RF coupling with the processing chamber 100. The low frequency pulsing between 0.2 Hz and 20 Hz for the bias power supply 117 provides RF biasing which enhances deposited film density on the substrate for in-situ treatment and/or etch.

Advantageously, the electrostatic chuck 152 can be used for both the PECVD/PEALD deposition and in-situ etch/treatment process while having superior wafer edge coverage using the active far edge electrode 119. The electrostatic chuck 152 also has a reduced footprint due to the embedded ground electrode that helps prevent plasma light up, i.e., arcing, in the gaps as seen in previous approaches to conventional grounding of electrostatic chucks.

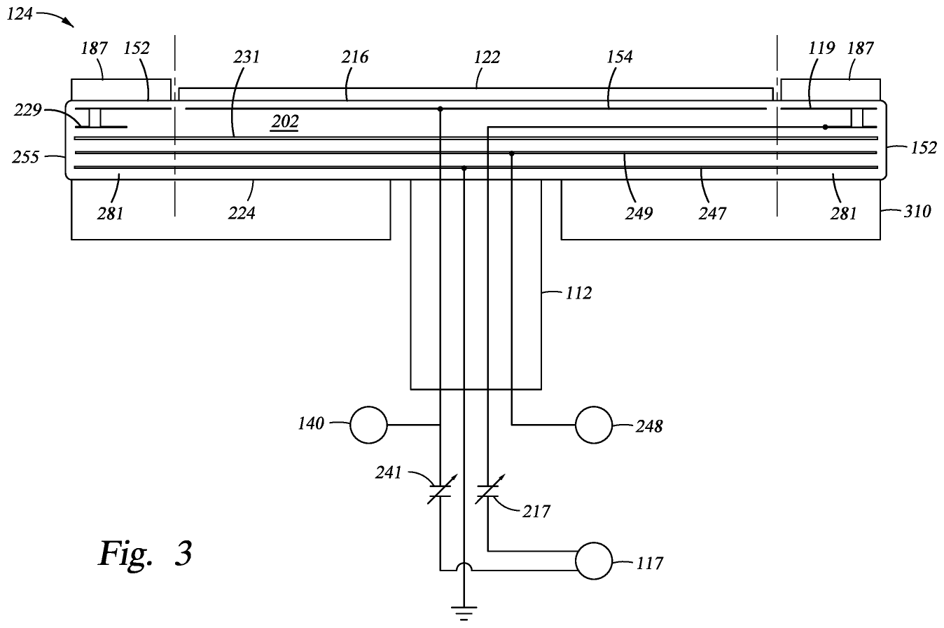

FIG. 3 depicts a schematic partial side view of a substrate support 124 in accordance with another example of the present disclosure. The substrate support 124 is substantially as described above with respect to FIGS. 2A and 2B. In yet another example of substrate support 124, a cooling base 310 is disposed below the second side of the electrostatic chuck 152.

The cooling base 310 may be coupled to the electrostatic chuck through mechanical fasteners. For example, the cooling base 310 may be bolted to the electrostatic chuck 152. Alternately, the cooling base 310 may be coupled to the electrostatic chuck by a chemical bond, such as an adhesive or through diffusion or welding.

In some examples, the cooling base 310 is made of an electrically conductive material, for example, aluminum (Al). The cooling base 310 in some examples may couple to the bias power supply 117. The cooling base 310 may be energized by the bias power supply 117 and relied on as an electrode for biasing the plasma.

Coolant may be flowed through the cooling base 310 to decrease the operating temperature of the electrostatic chuck 152. Advantageously, the substrate support as described above may be able to additionally operate at temperatures below 600 degrees Celsius, such as around 200 degrees Celsius.

While the foregoing is directed to implementations of the present invention, other and further implementations of the invention may be devised without departing from the basic scope thereof, and the scope thereof is determined by the claims that follow.

1. A substrate support for use in a substrate processing chamber, the substrate support comprising:
a ceramic electrostatic chuck having a body, the body having an outer diameter, a first side configured to support a substrate and a second side opposite the first side, wherein body comprises;
a chucking electrode;
an active far edge electrode disposed adjacent the chucking electrode;
a floating mesh disposed below the chucking electrode;
a heating element disposed below the floating mesh; and
a ground mesh disposed below the heating element, wherein the ground mesh is adjacent the second side.

2. The substrate support of claim 1 wherein the chucking electrode and the active far edge electrode may be a distance of about 1.5 mm to about 3 mm below the first side.

3. The substrate support of claim 1 wherein the floating mesh is spaced about 2 mm to about 3 mm from the outer diameter.

4. The substrate support of claim 2 further comprising:
a spoke mesh coupled to the active far edge electrode and disposed below the active far edge electrode and the chucking electrode, wherein the floating mesh is disposed a distance of between about 0.5 mm and about 2.0 mm below the spoke mesh.

5. The substrate support of claim 3 wherein the heating element is disposed a distance of between about 4 mm and about 6 mm below the floating mesh.

6. The substrate support of claim 5 wherein the ground mesh is disposed a distance of between about 3 mm and about 5 mm below the heating element.

7. The substrate support of claim 6 wherein the ground mesh may be disposed a distance of between about 1.5 mm and about 3.5 mm above the second side.

8. The substrate support of claim 1 wherein the chucking electrode is configured to supply coupled low frequency pulsing between 0.2 Hz and 20 Hz.

9. The substrate support of claim 8 wherein the active far edge electrode is configured to operate independently of the chucking electrode.

10. The substrate support of claim 9 wherein the active far edge electrode is configured to operate from the power source coupled to the chucking electrode.

11. A processing chamber, comprising:
a chamber body; and
a substrate support disposed within the chamber body, the substrate support comprising:
a ceramic electrostatic chuck having a body, the body having an outer diameter, a first side configured to support a substrate and a second side opposite the first side, wherein body comprises;
a chucking electrode;
an active far edge electrode disposed adjacent the chucking electrode;
a floating mesh disposed below the chucking electrode;
a heating element disposed below the floating mesh; and
a ground mesh disposed below the heating element, wherein the ground mesh is adjacent the second side.

12. The processing chamber of claim 10 wherein the chucking electrodes and the active far edge electrode may be a distance of about 1.5 mm to about 3 mm below the first side.

13. The processing chamber of claim 11 wherein the floating mesh is spaced about 2 mm to about 3 mm from the outer diameter.

14. The processing chamber of claim 12 further comprising:
a spoke mesh coupled to the active far edge electrode and disposed below the active far edge electrode and the chucking electrode, wherein the floating mesh is disposed a distance of between about 0.5 mm and about 2.0 mm below the spoke mesh.

15. The processing chamber of claim 12 wherein the heating element is disposed a distance of between about 4 mm and about 6 mm below the floating mesh.

16. The processing chamber of claim 15 wherein the ground mesh is disposed a distance of between about 3 mm and about 5 mm below the heating element.

17. The processing chamber of claim 16 wherein the ground mesh may be disposed a distance of between about 1.5 mm and about 3.5 mm above the second side.

18. The processing chamber of claim 11 further comprising:
a power source, wherein the power source supplies the chucking electrode a low frequency pulse between 0.2 Hz and 20 Hz.

19. The processing chamber of claim 17 wherein the active far edge electrode is configured to operate independently of the chucking electrode.

20. The processing chamber of claim 18 wherein the active far edge electrode is coupled to the power source.
